(19) United States
(12) Patent Application Publication
(10) Pub. No.: US 2013/0193612 A1
(43) Pub. Date: Aug. 1, 2013

(54) SEMICONDUCTOR DEVICE MANUFACTURING METHOD AND MANUFACTURING EQUIPMENT

(71) Applicant: Kabushiki Kaisha Toshiba, Tokyo (JP)

(72) Inventor: Hiroshi Watabe, Oita (JP)

(73) Assignee: Kabushiki Kaisha Toshiba, Tokyo (JP)

(21) Appl. No.: 13/751,849

(22) Filed: Jan. 28, 2013

(30) Foreign Application Priority Data
Jan. 31, 2012 (JP) 2012-018208

(51) Int. Cl. H01L 25/00

(52) U.S. Cl. CPC H01L 25/00
USPC 264/261; 425/110

(57) ABSTRACT

A semiconductor device manufacturing method comprises: stacking semiconductor chips on a substrate, applying an underfill material around the semiconductor chips, inclining the substrate, heating the substrate to decrease the viscosity of the underfill material, and hardening the underfill material after gaps in the semiconductor chips have been filled with the underfill material. The method allows gaps in the semiconductor chips between chips and other chips and chips in the substrate to be filled with the underfill material, which may be, for example, a thermoset resin . The method allows the gaps to be filled quickly and without leaving unfilled voids in the semiconductor device that might adversely affect device performance.

### CROSS-REFERENCE TO RELATED APPLICATION

This application is based upon and claims the benefit of priority from Japanese Patent Application No. 2012-018208, filed Jan. 31, 2012; the entire contents of which are incorporated herein by reference.

### FIELD

Embodiments described herein relate generally to a semiconductor device manufacturing method and semiconductor device manufacturing equipment.

### BACKGROUND

Statistical increases in operation speed and density of stacked semiconductor device can be measured based on the thickness of layers of several semiconductor chips found on the top on a wiring substrate. For the semiconductor devices of this nature, underfill material (thermoset resin) is filled between gaps of the substrate and the semiconductor chips, as well as a space between each semiconductor chip. The underfill material is supplied through the use of a capillary action found on the side of the semiconductor chips, and is made to permeate between the substrate and the semiconductor chips as well as between each semiconductor chip. If this filling of the underfill material does not go smoothly, and spaces are left unfilled, it's difficult to improve the reliability of the semiconductor chips. Thus, with the substrate and the semiconductor chips heated, the amount of the underfill material supplied to the substrate and the semiconductor chips usually depends on the drop in viscosity of the underfill material.

However, up until now, when dealing with semiconductor chips that stack high on top of each other with this method, the spaces between highly positioned semiconductor chips become difficult for the underfill material to reach due to its drop in viscosity.

### DESCRIPTION OF THE DRAWINGS

FIG. 1 is a schematic side view depicting a portion of a manufacturing process of a semiconductor device according to one embodiment.

FIG. 2 is a schematic side view depicting another portion of the manufacturing process of the semiconductor device after the step shown in FIG. 1.

FIG. 3 is a schematic side view depicting a further portion of the manufacturing process of the semiconductor device after the step shown in FIG. 2.

FIG. 4 is a schematic side view depicting a semiconductor device made in accordance with one embodiment.

### DETAILED DESCRIPTION

In general, the following will use the figures to explain the form of an embodiment.

The problem addressed is providing a manufacturing process for semiconductor devices that allows enough underfill material to reach the spaces between the highest positioned semiconductor chips in a stack of semiconductor chips even when dealing with several semiconductor chips that stack on top of each other, and along with it the accompanying manufacturing equipment.

A semiconductor device manufacturing method comprises: (a) arranging semiconductor chips in a stack on a substrate; (b) applying an underfill material around the stack of semiconductor chips; (c) inclining the substrate; (d) heating the substrate to decrease the viscosity of the underfill material; and (e) hardening the underfill material after gaps in the stack have been filled with the underfill material.

A manufacturing process of the semiconductor device may also described as follows: (a) stacking semiconductor chips on top of each other on a substrate; (b) positioning the substrate horizontally, and applying underfill around the semiconductor chips; (c) inclining the substrate so that the underfill material applied around the semiconductor chips can reach the upper regions of the semiconductor chips; (d) heating the underfill material to promote filling the spaces between the gaps of the inclined substrate and the semiconductor chips, as well as the space between each semiconductor chip; and (e) hardening the underfill material.

### First Embodiment

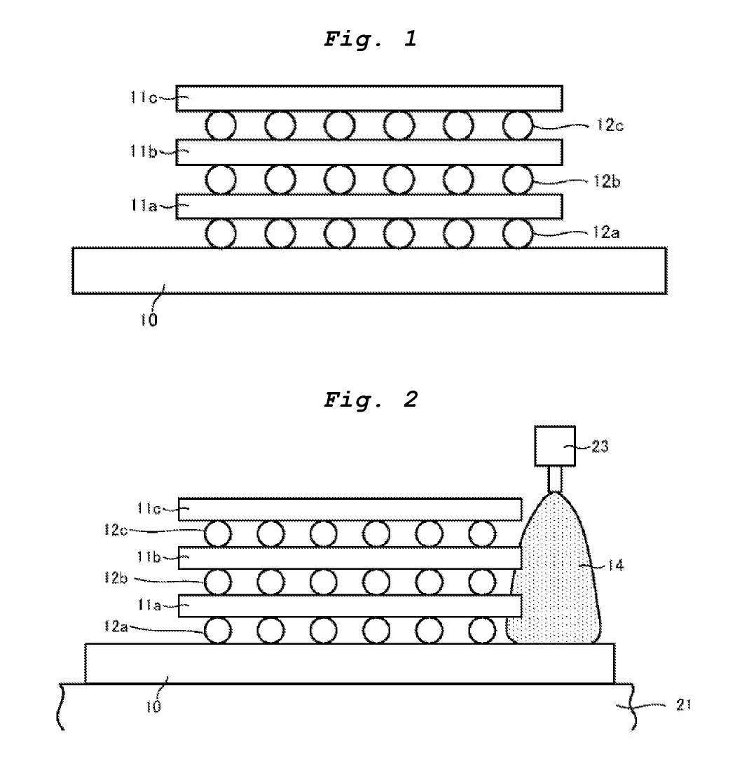

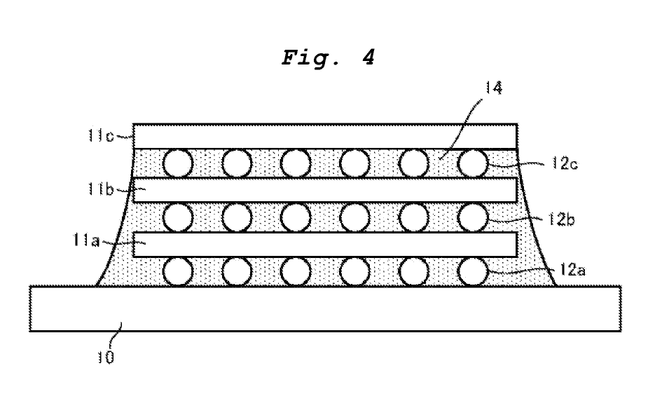

FIG. 1 through FIG. 3 are side view figures that are used to explain the manufacturing process of the semiconductor device according to a first embodiment. FIG. 4 depicts the actual finished manufactured semiconductor device from a side view.

For this embodiment, the manufacturing process is only described through the use of three layers of stacked semiconductor chips, but there is no particular limit to how many layers of semiconductor chips can be used. For example, this manufacture process can apply to two layers as well as four or more layers.

For the example embodiment, as shown in FIG. 1, the substrate 10 is prepared, and on top of the substrate are several semiconductor devices (semiconductor chips) 11a to 11c that are connected, in order a to c, through flip chip interconnection (or the like), and layered (stacked) on top of each other.

First, the lowest positioned semiconductor chip 11a and the substrate 10 are made to be facing opposite of each other. On the opposing surfaces of both the semiconductor chip 11a and the substrate 10, electrode pads (not shown in the figure) are formed between them. These facing electrode pads are connected through metal bumps 12a such as solder bumps that allows a connection to semiconductor chip 11a from substrate 10. Next, the second lowest positioned semiconductor chip 11b and the first semiconductor chip 11a are made to be facing opposite of each other. In the same way as semiconductor chip 11a and the substrate 10, on opposing surfaces of both the semiconductor chip 11a and the semiconductor chip 11b, are formed with electrode pads (not shown), and between these electrode pads are metal bumps 12b such as solder bumps that allow a connection from 11a to 11b. Lastly, just as before, semiconductor chip 11b and the semiconductor chip 11c are made to be facing opposite of each other. In the same way as semiconductor chip 11a and the semiconductor chip 11b, on opposing surfaces of both the semiconductor chip 11b and the semiconductor chip 11c, are formed with electrode pads (not shown), and these electrode pads are connected via metal bumps 12c such as solder bumps that allow a connection to 11c from 11b.

All semiconductor chips 11a to 11c are made from silicon semiconductor substrates. Each semiconductor chip comes equipped with through-electrodes (Not illustrated in diagrams). The substrate 10 can have a backing made from resin, ceramic or glass, silicon and a chip scale package.

Once semiconductor chips 11a to 11c, placed upon substrate 10, are properly stacked and the electric connections firmly secured, as shown in FIG. 2, the substrate on which the semiconductor chips 11a to 11c are placed, is placed on stand 21, which contains a heating apparatus (not shown in the figure) and maintains the position of the substrate. Thermoset resin 14, which acts as the underfill material, is applied next to the stacked semiconductor chips 11a to 11c at a temperature, for example, of 23 to 25° C. (approximately room temperature).

There may be a dispenser device 23 for administering the thermoset resin 14. Other mixtures such as epoxy resin, acrylic resin, amine resin, silicone resin, and polyimide resin into which filler such as silica is mixed may be used as the thermoset resin 14.

For these mixtures, it is favorable to have a viscosity of 0.05 to 0.5 Pa·s at the temperature of the application (coating temperature). Having a viscosity of 0.1 to 0.3 Pa·s at the temperature of the application is even better. However, if at the temperature of the application, viscosity is less than 0.05 Pa·s then, the applied resin may spread (flow) around stacked semiconductor chips 11a to 11c, too much, and thermoset resin 14 will have trouble reaching the uppermost spaces of semiconductor chip 11c.

If the viscosity exceeds 0.5 Pa·s at the coating temperature, then not only does the application found around semiconductor chips 11a to 11c drop in effectiveness, there is the risk that the spaces between semiconductor chips 11a to 11c will not be filled completely. Thus, there is a risk that air pockets (or voids) might occur due to the lower fluidity of the thermoset resin 14 and the long time it takes to fill the gaps.

The viscosity of the resin can be measured by a Brookfield type viscosity measurement apparatus, for example.

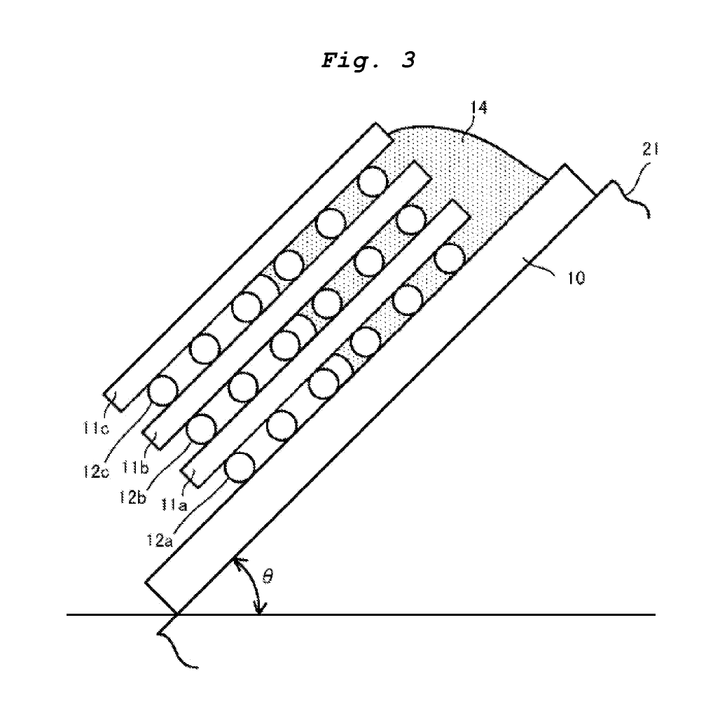

Next, as displayed in FIG. 3, the substrate 10 and the stacked semiconductor chips 11a to 11c are made to tilt along with the stand 21 in order for the thermoset resin 14 to reach the upper regions of the semiconductor chips. From the horizontal position, an angle of inclination θ within the range of 10 to 90° is favorable. An angle of inclination within the range of 20 to 45° is even more favorable. With an angle of inclination θ less than 10°, there is a risk that, after production, the thermoset resin 14 will be unable to properly fill the spaces between the upper chips of the semiconductor chips 11a to 11c. On the other hand, if the angle of inclination θ is over 90°, there is a risk that thermoset resin 14 will spread past the top of the semiconductor chip 11c. The stand 21 can be made so that it can be fixed into any angle of inclination.

In a state where the substrate 10 and the semiconductor chips 11a to 11c are tilted with the stand 21, the substrate 10 and the semiconductor chips 11a to 11c are heated by the heating apparatus built into the stand 21.

This heating causes a drop in the viscosity of the thermoset resin 14 applied around the semiconductor chips 11a to 11c and therefore an increase in fluidity. This allows the thermoset resin 14 more readily to permeate and fill the open spaces of the device by the capillary action—specifically, the gaps being the space between the substrate 10 and the first semiconductor chip 11a, the space between the first semiconductor chip 11a and the second semiconductor chip 11b, and the space between the second semiconductor chip 11b and the third semiconductor chip 11c.

The heating temperature of substrate 10 and the stacked semiconductor chips 11a to 11c should be at least 10° C. higher than the temperature of thermoset resin 14 when it was applied around the semiconductor chips 11a to 11c. Or the temperature may be raised to a temperature at which viscosity of the thermoset resin 14 becomes 1/10 of its initial, as-applied viscosity.

When the heating temperature is less than 10° C. or viscosity is more than 1/10, viscosity of the thermoset resin 14 may not be low enough to fill all the spaces between the semiconductor chips 11a to 11c, and it will anyways take a longer time for any spaces to be filled.

It would be favorable to keep the temperature of the substrate 10 and the stacked semiconductor chips 11a to 11c to a range 20-80° C. higher than the as-applied temperature of thermoset resin 14, or possibly the temperature at which the viscosity of thermoset resin 14 is within 1/10 to 1/300 range of its as-applied viscosity. Even more favorable would be to keep the temperature of the substrate 10 and the stacked semiconductor chips 11a to 11c to the 60-80° C. higher than as-applied temperature of the thermoset resin 14, or possibly the temperature at which the thermoset resin 14 becomes within 1/100 to 1/300 range of its as-applied viscosity.

In this example, the substrate 10 and the semiconductor chips 11a to 11c are heated by the heating apparatus built into stand 21 but contemplated heating methods are not limited to only this method. For example, the substrate 10 and the semiconductor chips 11a to 11c that sit on stand 21 could also be heated from atmospheric heat within a heated area (e.g., an oven). Another possibility would be directly heating the thermosetting resin 14 by blowing an inert gas of a fixed temperature onto the substrate. The semiconductor chips 11a to 11c or the substrate 10 could also be heated through electric currents (resistance heating). Depending on the situation, it is possible to use a combination of these methods. But from the standpoint of equipment simplicity it may be preferable to include the heating apparatus within the stand 21 because it makes heat management simple.

After the gaps (“gaps” include: the spaces between the substrate 10 and the first semiconductor chip 11a, the space between the first semiconductor chip 11a and the second semiconductor chip 11b, and the space between the second semiconductor chip 11b and the third semiconductor chip 11c) are filled with thermoset resin 14, the filled thermoset resin 14 is further heated and which causes it to hardens (or set). As portrayed in FIG. 4, semiconductor chips 11a to 11c placed on substrate 10 are properly stacked, and thermoset resin 14 fills each gap of the device, thereby completing the manufacture of the stacked semiconductor device.

With the thermoset resin 14 hardened, it is then okay for the substrate 10 and the semiconductor chips 11a to 11c that rest on the stand 21, to return to their horizontal position. It is also okay for the stand 21 to stay in its inclined position. However, from the standpoint of keeping the fillet formed on the semiconductor chips 11a and 11b in an uniform shape and position, it is favorable to let the thermoset resin 14 harden while the stand is in the horizontal position.

In the above explanation of the manufacturing method to produce semiconductor devices, while the substrate 10, which has placed on it stacked semiconductors 11a to 11c, is positioned horizontally, thermoset resin 14 is applied around the semiconductor chips 11a to 11c. Next, the substrate 10 is made to incline at an angle, after which the thermoset resin 14 is heated so that the space between the substrate 10 and the first semiconductor chip 11a is more easily filled, and each space between the semiconductor chips 11a to 11c, (the space between the semiconductor chips 11a and 11b, and the space between the semiconductor chip 11b and the semiconductor chip 11c which is at a higher position) is properly filled.

### Other Embodiments

In the first embodiment, the thermoset resin 14 is heated and the operation to fill the space between the substrate 10 and the first semiconductor chip 11a and each space between the semiconductor chips 11a to 11c, is completed. The stand 21 may be made to incline even more, either intermittently or continuously. In other words, this means that the angle θ of inclination of the stand 21 at an even deeper angle θ than the angle θ shown in FIG. 3 of the manufacturing process. It is also possible to install a controller device that will manage the angle of inclination θ of the stand 21.

This method is very effective for situations where the number of semiconductor chip layers passes 10. When the number of semiconductor chip layers becomes too large, there is a risk that the spaces between the higher positioned semiconductor chips will not be properly filled with just the inclination of the stand 21, which is the manufacturing process as shown in FIG. 3. If the stand 21 is inclined at an even greater angle than what is shown in FIG. 3, the thermoset resin 14 will be able to quickly fill the spaces of stacked semiconductor chips 11a to 11c even if the number of layers becomes larger. For the manufacturing process, it is recommended that the angle of inclination θ of the stand 21 does not pass 90°. Once the angle of inclination θ passes 90°, there is a risk that the thermoset resin 14 will spill past the top semiconductor chip 11c.

In the first embodiment, it is shown in FIG. 1, that for the manufacturing process, semiconductor chips 11a to 11c are placed onto the substrate 10 in flip chip order, but it is also ok to first connect semiconductor chips 11a to 11c together, and then place it on top of substrate 10.

In the first embodiment previously explained, the finished substrate 10 holds semiconductor chips 11a to 11c, but it is also possible to use a larger substrate with a greater capacity for a larger amount of semiconductor devices. In this case, semiconductor devices of the previously explained embodiment are stacked onto a large size substrate while the substrate is in the horizontal position. Next, in the same fashion as the first embodiment, thermoset resin 14 is applied around the semiconductor chips stacked on the substrate, the substrate is inclined, thermoset resin is further heated, the spaces between the substrate and the semiconductor chips and the spaces between each chip are filled with the thermoset resin, and the thermoset resin is made to harden. Afterwards a diamond blade saw (or other cutting tool) is used to cut the substrate, the semiconductor chips are stacked, and the thermoset resin that fills each gap is segmented. This method uses high semiconductor device capacity substrates, and therefore it would allow for an increase in the productivity of the semiconductor device.

According to the above description of one of these embodiments, while substrate 10, which has placed on it the stacked semiconductor chips 11a to 11c, is positioned horizontally, thermoset resin 14 is applied around the stacked semiconductor chips 11a to 11c. Next, the substrate is made to incline at an angle, after which the thermoset resin 14 is heated so that the space between substrate 10 and the first semiconductor chip is filled, each subsequent space between semiconductor chips is filled, and the higher up spaces between semiconductor chips are also filled completing the manufacture of the stacked semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method comprising:
(a) stacking semiconductor chips on a substrate;
(b) applying an underfill material around the semiconductor chips;
(c) inclining the substrate;
(d) heating the substrate to decrease the viscosity of the underfill material; and
(e) hardening the underfill material after gaps in the semiconductor chips have been filled with the underfill material.

2. The semiconductor device manufacturing method according to claim 1, wherein heating the substrate in the step (d) raises a temperature of the substrate by more than 10° C.

3. The semiconductor device manufacturing method according to claim 1, wherein heating the substrate in step (d) causes the viscosity of the underfill material to decrease by 90% or more from an initial viscosity.

4. The semiconductor device manufacturing method according to claim 1, wherein, in the step (c), the substrate is inclined to an angle of 10° or more from horizontal.

5. The semiconductor device manufacturing method according to claim 1, wherein step (d) further comprises:
inclining the substrate to a greater angle from horizontal.

6. The semiconductor device manufacturing method according to claim 1, wherein inclining the substrate in step (c) includes several different angles of inclination.

7. The semiconductor device manufacturing method according to claim 1, wherein a coating device is used in step(b) for applying the underfill material.

8. The semiconductor device manufacturing method according to claim 1, wherein the underfill material is a thermoset resin.

9. The semiconductor device manufacturing method according to claim 8, wherein the thermoset resin is selected from a group of materials consisting of an epoxy resin, acrylic resin, amine resin, silicone resin, and polyimide resin.

10. The semiconductor device manufacturing method according to claim 8, wherein the thermoset resin includes silica as a filler.

11. The semiconductor device manufacturing method according to claim 1, wherein step (b) is performed at approximately room temperature.

12. The semiconductor device manufacturing method according to claim 1, wherein hardening of the underfill material occurs by heating.

13. A method of manufacturing a semiconductor device comprising:
stacking semiconductor chips on a substrate, the semiconductor chips including gaps;
applying a thermoset resin to the semiconductor chips while the substrate is in a horizontal position;
inclining the substrate to an angle other than horizontal;
heating the substrate to a which decreases a viscosity of the thermoset resin by at least 90%; and
hardening the thermoset resin.

14. The method of claim 13, wherein the thermoset resin is applied at approximately room temperature, and the step of heating the substrate decreases the viscosity of the thermoset resin to between 1/100 and 1/300 of the viscosity of the thermoset resin at approximately room temperature.

15. The semiconductor device manufacturing method according to claim 14, wherein the thermoset resin is selected from a group of materials consisting of an epoxy resin, acrylic resin, amine resin, silicone resin, and polyimide resin.

16. The semiconductor device manufacturing method according to claim 14, the angle is between 10 and 90 degrees.

17. The semiconductor device manufacturing method according to claim 14, wherein the angle is intermittently changed.

18. An apparatus for manufacturing a semiconductor device having stacked semiconductor chips on a substrate, the apparatus comprising:
a section on which a semiconductor device having stacked semiconductor chips over a substrate is positioned horizontally;
a section configured to incline the substrate to a predetermined angle;
a section to which underfill material for the semiconductor device is applied
a section configured to heat the applied underfill material; and
a control section configured to control:
the section to which underfill material is applied to apply the underfill material,
the section configured to incline the substrate to the predetermined angle to incline the substrate, and
the section configured to heat the applied underfill material to heat the underfill material.

19. The apparatus of claim 18, wherein the predetermined angle is between 10 and 90 degrees from horizontal and a temperature of the applied underfill material is raised by at least 10° C. from an initial temperature.

20. The apparatus of claim 18, wherein the section configured to heat the applied underfill material is built in to the section on which the semiconductor device having multiple layers of semiconductor chips stacked over the substrate is positioned horizontally.
